(19) United States
(12) Patent Application Publication
(10) Pub. No.: US 2024/0145394 A1
(43) Pub. Date: May 2, 2024

(54) INTERPOSER POWER CORRIDOR

(71) Applicant: Intel Corporation, Santa Clara, CA (US)

(72) Inventors: Poh Boon KHOO, Perai (MY); Jiun Hann SIR, Gelugor (MY)

(21) Appl. No.: 18/050,533

(22) Filed: Oct. 28, 2022

(51) Int. Cl. H01L 23/538; H01L 21/48; H01L 23/498; H01L 25/16

(52) U.S. Cl. CPC H01L 23/5384; H01L 21/4857; H01L 23/49816; H01L 25/16; H01L 28/10

(57) ABSTRACT

The present disclosure is directed to a semiconductor platform having a printed circuit board with an interposer coupled thereto. The interposer includes a low-resistance metal layer that acts as a power corridor, and a first non-conductive layer and a second non-conductive layer, respectively, positioned on the top and bottom surfaces of the metal layer. In addition, the interposer also includes a plurality of vertical interconnects that provide electrical connections through the interposer. A semiconductor package and other components may be coupled to the interposer, for which the interposer provides a power corridor for the semiconductor package and the components, and to the print circuit board via the plurality of vertical interconnects.

### BACKGROUND

In integrated circuit design and fabrication, the need to improve performance and lower of costs are constant challenges. The continuing trend towards miniaturization, i.e., a reduction in the form factor for a printed circuit board (PCB) with a semiconductor package and various other components, may lead to lower material costs, as well as improved performance with more compact designs.

A conventional semiconductor platform, for example, having a semiconductor package and components, such as voltage regulators, that are coupled to a PCB through vias and lines/planes may have significant package real estate, i.e., 3-dimensional space, that may be used or eliminated. On the other hand, the semiconductor platform may be required to have increased power capabilities using high current lines, a significant number of capacitors, and a ball grid array that provides a wider power corridor. The components may further include inductors that may necessitate a need to avoid inductor coupling, i.e., noise, by placing input/output signal lines separated from the inductors. Furthermore, a power plane positioned in a PCB may require the use of anti-pad voids to accommodate high-speed input/output vertical interconnects that may affect the power distribution network and result in higher load line values and direct current resistance.

One approach to addressing the issues relating to increased power capabilities is to increase the form factor of the semiconductor or system platform, including layer count and board real estate. However, this approach is contrary to the drive for greater miniaturization, and consequently, another approach may be needed.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary conventional semiconductor platform;

FIG. 2 shows an exemplary semiconductor platform with an interposer having a power corridor according to an aspect of the present disclosure;

FIG. 3 shows an exemplary partial view of conventional solder balls positioned between a semiconductor package substrate and a printed circuit board;

FIG. 4 shows an exemplary interposer according to an aspect of the present disclosure;

FIG. 5A shows a representative cross-section view of another exemplary interposer and FIGS. 5B and 5C show representative top views at different levels of the exemplary interposer shown in FIG. 5A, according to an aspect of the present disclosure;

FIGS. 6A through 6J show exemplary method steps for forming a semiconductor platform according to another aspect of the present disclosure;

FIG. 7 shows a representative view of a ball grid array for a conventional semiconductor platform, which is provided for comparison with FIG. 8 that shows a representative view of a ball grid array for a present semiconductor platform according to another aspect of the present disclosure; and

FIG. 9 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure is directed to a semiconductor platform having a printed circuit board with an interposer with a power corridor. The interposer may include a low-resistance metal layer that acts as the power corridor, and a first non-conductive layer and a second non-conductive layer, respectively, positioned on the top and bottom surfaces of the metal layer. In addition, the interposer also includes a plurality of vertical interconnects that provide electrical connections through the interposer. A semiconductor package and other components may be coupled to the interposer and the print circuit board via the plurality of vertical interconnects, for which the interposer provides the power corridor for the semiconductor package and the components and the plurality of vertical interconnects provides coupling to a ground plane positioned in an upper layer of the printed circuit board.

In another aspect, the present disclosure is directed to an interposer for a semiconductor platform having a low-resistance metal layer with a top surface and a bottom surface, with the low-resistance metal layer providing a power corridor between a plurality of devices coupled to the top surface and a printed circuit board coupled to the bottom surface. In addition, a first non-conductive layer is positioned on the top surface of the metal layer and provided with a first pattern of openings for solder connections, and a second non-conductive layer is positioned on the bottom surface of the metal layer with a second pattern of openings for solder connections. The interposer also has a plurality of vertical interconnects formed in the low-resistance metal layer separated by non-conductive vertical separators.

In yet another aspect, the present disclosure is directed to a method that provides a low-resistance metal layer with a top surface and a bottom surface, and forming a plurality of vertical vias through the low-resistance metal layer. In addition, the method includes forming a first non-conductive layer positioned on the top surface of the low-resistance metal layer and a second non-conductive layer positioned on the bottom surface of the low-resistance metal layer and filling the plurality of vertical vias to form non-conductive vertical separators for a plurality of vertical interconnects in the low-resistance metal layer. The first non-conductive layer, the low-resistance metal layer, the second non-conductive layer, and the plurality of vertical interconnects form an interposer with a power corridor. The method also includes forming a first pattern of openings for solder connections in the first non-conductive layer and a second pattern of openings for solder connections in the second non-conductive layer.

The technical advantages of the present disclosure include, but are limited to:
(i) Improved electrical performance by having a power distribution network that uses a thick metal layer in an interposer as a power corridor, the reduction of loop inductance by having a ground plane in an upper layer of the printed circuit board, and the prevention of solder ball bridging by using patterned openings on molded non-conductive layers on an interposer for solder ball connections;
(ii) A reduction in device form factor through the possible removal of power planes from semiconductor packages, reduction in ball grid array sizes through fewer and/or smaller solder balls, and reduction in package layer count; and
(iii) A reduction in platform form factor through the elimination of plated-through-hole vias in the printed circuit board, as well as greater flexibility in the placement of input/output vertical connections and lines in the printed circuit board.

To more readily understand and put into practical effect the present semiconductor platform with the present interposer, including methods for making, which may be used for electronic assemblies to improve their performance, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

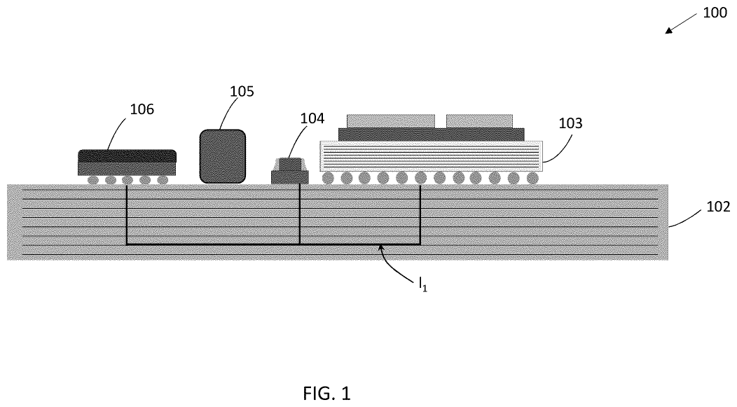

FIG. 1 shows an exemplary conventional semiconductor platform 100 that may include a printed circuit board (PCB) or motherboard 102 with a semiconductor package 103 and other components. The semiconductor platform 100 may have passive components 104 and 105, which may be a capacitor and an inductor, respectively, and power components 106, such as voltage regulators (VRs) or power management integrated circuits (PMICs). One or more of these devices/components on the PCB may be coupled to a ground plane l₁ that is positioned in a lower portion of the PCB. It may be possible to “redesign” a conventional semiconductor platform to better use the available spaces as well as improve its performance.

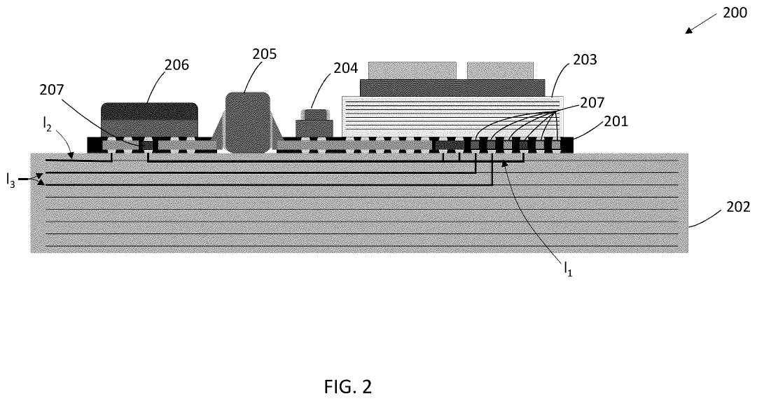

FIG. 2 shows an exemplary semiconductor platform 200 with an interposer 201 according to an aspect of the present disclosure. As further discussed in the figures below, the interposer 201 may include a plurality of vertical interconnects 207 and may be positioned between a PCB 202 between a semiconductor package 203, with other components, such as a first passive device 204, e.g., a capacitor, and a voltage regulator 206, also positioned on and coupled to the interposer 201. One or more of the plurality of vertical interconnects 207 may be coupled to a ground plane l₁ and input/output signal lines l₃. In an aspect, the ground plane l₁ may be formed without voids, i.e., openings or breaks, and may be placed, for example, on an Li level or other upper layers of a printed circuit board under an inductor, which may provide noise shielding.

According to the present disclosure, the interposer 201 may provide a “power corridor” and may be coupled to a power source (not shown) via a power line l₂. The present power corridor may provide low resistance power delivery; in particular, between the voltage regulator 206, the capacitor 204, the semiconductor package 203, and the PCB 202. A second passive device 205, e.g., an inductor, may be positioned on the PCB 202 and coupled to the interposer 201.

It should be understood that the present semiconductor package may include a variety of different semiconductor devices, for example, a central processing unit (CPU), a graphics processing unit, chiplets, system-on-chips, etc. In addition, the present semiconductor package may include a variety of different passive devices, for example, resistors, capacitors, inductors, transformers, diodes, thermistors, varactors, transducers, etc.

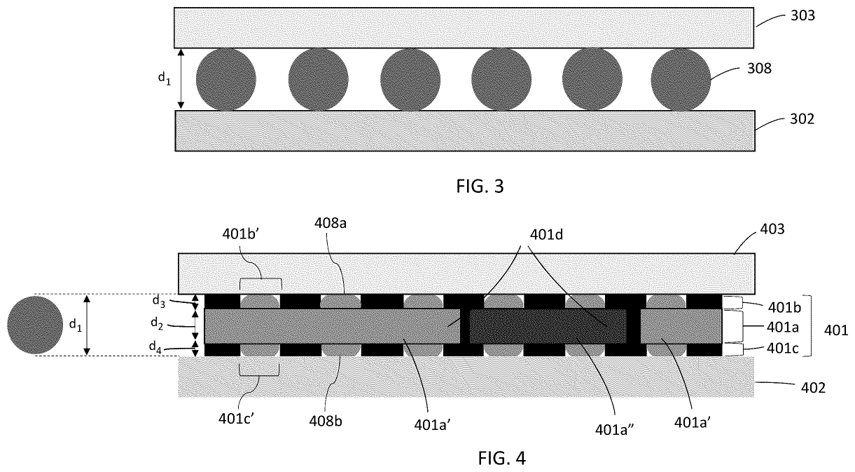

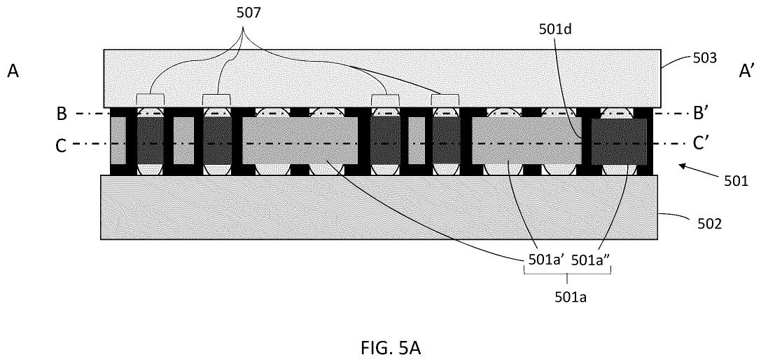

FIG. 3 shows an exemplary partial view of conventional solder balls 308 positioned between a semiconductor package substrate 303 and a printed circuit board 302. The solder balls 308 may have a diameter d₁, which may have a size in the range of approximately 200 μm to 500 μm depending on the overall system requirements, and will typically provide the electrical connections between the semiconductor package substrate 303 and the printed circuit board 302. In an aspect, for example, the diameter d₁ may be approximately 286 μm. In the present disclosure, all of the solder balls 308 may be replaced by a present interposer as shown in FIG. 4.

FIG. 4 shows an exemplary interposer 401 according to an aspect of the present disclosure. The interposer 401 may be positioned between a printed circuit board 402 and package substrate 403 and provide electrical connections between them. In an aspect, the interposer 401 may include a thick, low resistance conductive layer 401a having top and bottom surfaces, a non-conductive layer 401b on the top surface of the conductive layer 401a and a non-conductive layer 401c on the bottom surface of the conductive layer 401a, with the conductive layer 401a having a plurality of non-conductive vertical separators 401d that separate the conductor layer 401a into different connection vias and regions, such as regions 401a′ and 401a″. The regions 401a′ may be used for power connections and regions 401a″ may be used for ground connections.

In another aspect, as shown in FIG. 4, the low resistance conductive layer 401a may have a thickness of d₂, the non-conductive layer 401b may have a thickness of d₃, and the non-conductive layer 401c may have a thickness of d₄, which may have a combined thickness of a typically sized solder ball d₁. For example, the diameter d₁ of a typical solder ball may be approximately 286 μm, and if the present disclosure seeks to replace such solder balls, the thickness of d₂ of the conductive layer 401a may be approximately 126 μm, the thickness of d₃ of the non-conductive layer 401b may be approximately 80 μm, and the thickness of d₄ of the non-conductive layer 401c may be approximately 80 μm. It should be understood that the thickness for the dimensions d₂, d₃, and d₄ will be dependent on the overall system requirements for a semiconductor platform.

In a further aspect, to provide the power corridor of the present disclosure, the thickness d₂ of the conductive layer 401a may have a thickness in the range of approximately 50 μm to 200 μm, which may be 4-5 times thicker than a thickness for a typical power plane used in a semiconductor package substrate, e.g., approximately 15 μm, or for a printed circuit board, e.g., approximately 25 μm. In an aspect, the conductive layer 401a may be made of a metal, such as copper. In an aspect, the thickness d₂ of the low resistance conductive layer 401a may be greater than 120 μm.

In yet another aspect, the non-conductive layer 401b may have a first pattern of openings 401b′ that may be filled with solder paste 408a for configuring connections with the semiconductor package substrate 403, and the non-conductive layer 401c may have a second pattern of openings 401c′ that may be filled with solder paste 408b for configuring connections with the printed circuit board 402. In the aspect shown in FIG. 4, the first and second pattern of openings may be identical to provide a “balanced” configuration for electrical connections between the printed circuit board 402 and the semiconductor package substrate 403. It is within the scope of the present disclosure to have the first and second pattern of openings be different from the other as needed for particular design layouts.

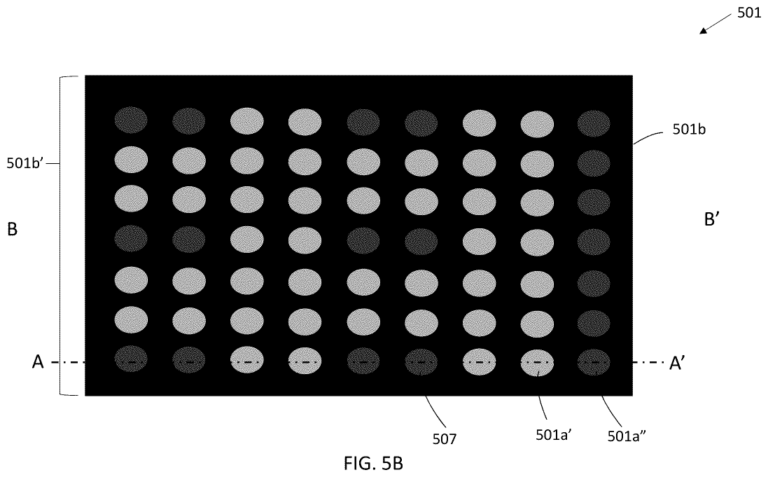

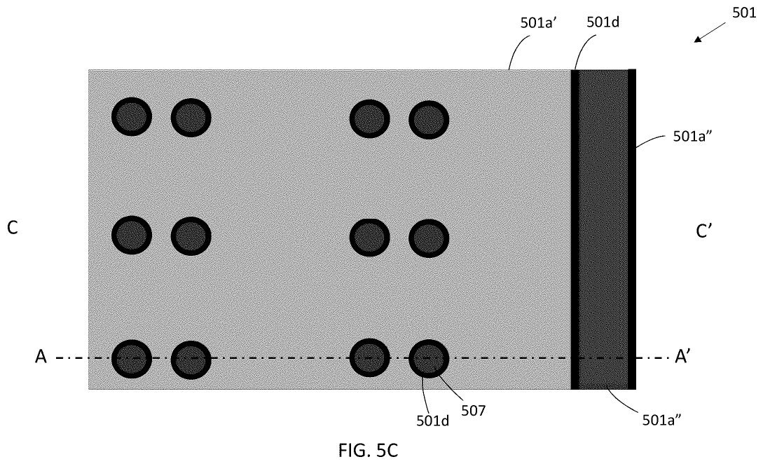

FIG. 5A shows a representative partial cross-section view along an A-A′ line of a semiconductor platform with an exemplary interposer 501, according to an aspect of the present disclosure. The interposer 501 may have a thick conductive layer 501a, with regions 501a′ and 501a″ and a plurality of vertical interconnects 507. In an aspect, the interposer 501 may provide a power corridor between a package substrate 503 and a printed circuit board 502.

In addition, FIG. 5B shows a representative top view at a B-B′ level and FIG. 5C shows a representative top view at a C-C′ level of the interposer 501 shown in FIG. 5A. In FIG. 5B, a non-conductive layer 501b on the top surface of the interposer 501 may have a first pattern 501b′ that provides openings for forming interconnects the regions 501a′ and 501a″ below, and vertical interconnect 507. In FIG. 5C, the interposer 501 may have regions 501a′ and 501a″ separated by a non-conductive vertical separator 501d, and the plurality of vertical interconnects 507 may also have non-conductive vertical separator 501d to provide electrical isolation from the region 501a′.

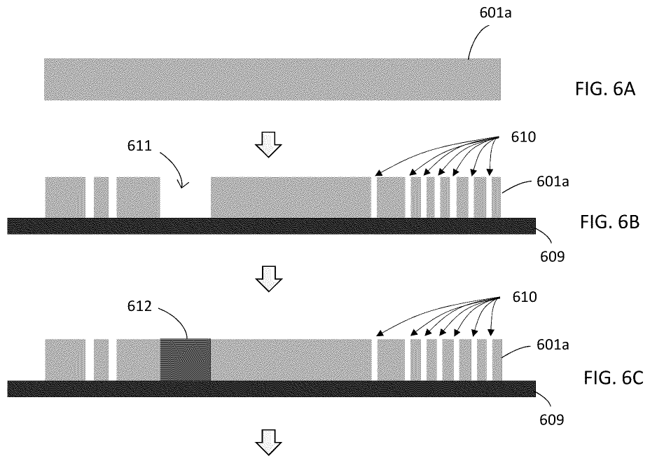

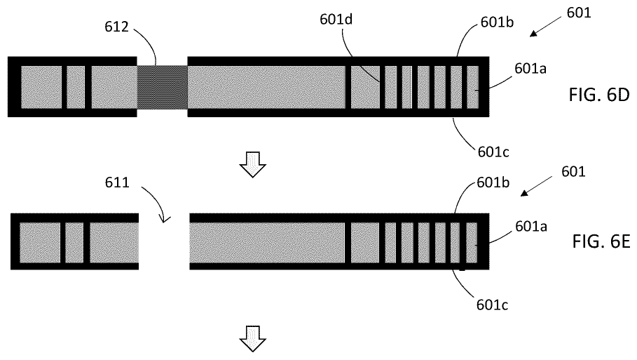

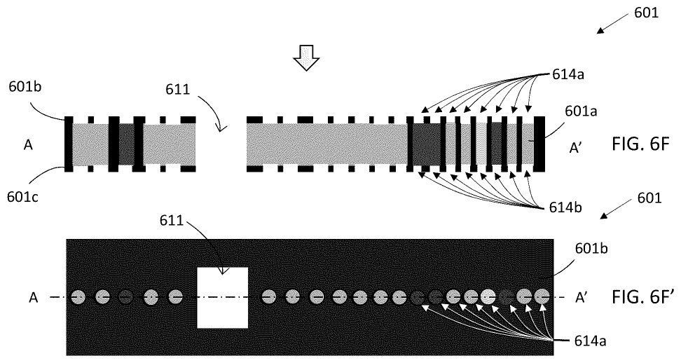

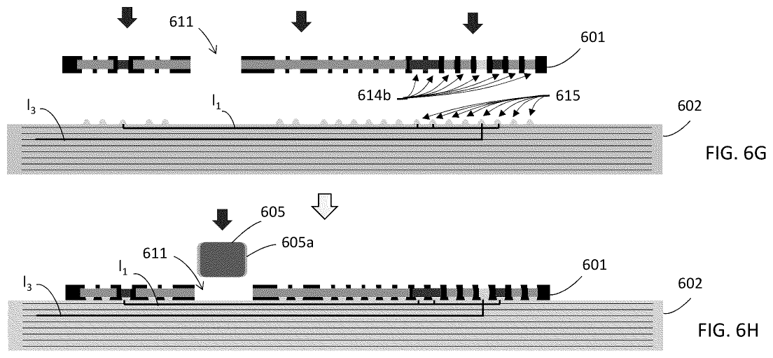

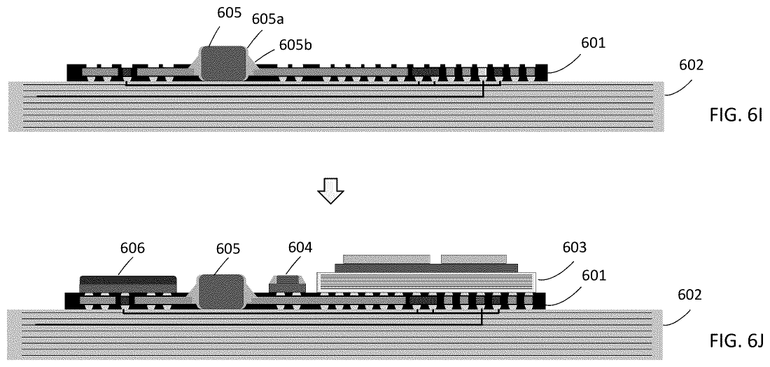

FIGS. 6A through 6J show exemplary method steps for forming a semiconductor platform according to another aspect of the present disclosure. It will be apparent to those ordinary skilled practitioners that the process operations disclosed herein below may be modified without departing from the spirit of the present disclosure.

FIG. 6A shows a low-resistance, thick conductive layer 601a, which is typically provided as foil or sheet that may be unrolled and cut to size. In an aspect, the thick conductive layer 601a is a copper foil.

In FIG. 6B, the thick conductive layer 601a may be mounted on a carrier 609, and thereafter, a plurality of vertical openings 610 may be formed in the conductive layer 601a using dry film lithography patterning and etching, laser drilling, waterjet drilling, or mechanical drilling process. A space 611 may be formed in the conductive layer 601a to accommodate devices that may be placed on a printed circuit board.

In FIG. 6C, a sacrificial material 612 may be deposited by a conventional deposition process to maintain the space 611 during subsequent operations. The sacrificial material 612 may, for example, be a polyvinyl alcohol.

In FIG. 6D, the thick conductive layer 601a may be placed in a molding tool, a first non-conductive layer 601b formed on its top surface, and the plurality of vertical openings 610 may be at least partially filled. The thick conductive layer 601a may be inverted and the carrier 609 removed and further molding may be performed to form a second non-conductive layer 601c on its bottoms surface, as well as filling any remaining unfilled portions of the plurality of vertical opening 610. The first and second non-conductive layers 601b and 601c may be made of dielectric material, such as an epoxy polymer resin, a silicone, or a polyimide material, which may be formed by conventional deposition methods, such as injection molding, spin coating, or dispensing process.

In FIG. 6E, the space 611 may be re-formed by removing the sacrificial material 612, as well as removing the portions of the first and second non-conductive layers 601b and 601c covering the sacrificial materials 612.

In FIG. 6F, a first pattern of openings 614a may be formed in the first non-conductive layer 601b, and a second pattern of openings 614b may be formed in the second non-conductive layer 601c. In FIG. 6F′, a top view of the interposer 601 is shown. The first pattern of openings 614a in the first non-conductive layer 601b, along the section line A-A′ only, and the space 611 are shown.

In FIG. 6G, the interposer 601 may be mounted onto a printed circuit board 602, with the second pattern of openings 614b aligned with a plurality of solder bump 615. The solder bumps 615 may, for example, be connected to a ground plane l₁ and a signal line l₃. The interposer 601 may be attached by standard surface mount technology, such as solder reflow processes and other assembly processes.

In FIG. 6H, a “tall” passive device 605 having a height greater than the interposer 601, such as an inductor, may be placed in the space 611 and attached to the printed circuit board 602. Alternatively, the tall passive device 605 may be first mounted on the printed circuit board 602 prior to the placement of the interposer 601. The tall passive device 605 may also have contacts 605a as shown.

In FIG. 6I, the contact 605a of the tall passive device 605 may be coupled to conductive layer 601a of the interposer 601 using a solder paste 605b.

In FIG. 6J, the mounting of a semiconductor package 603, a second passive device 604 (e.g., a capacitor), and a voltage or power regulating component 606 onto the interposer 601 is shown. The mounting of these components may be performed using conventional surface mounting technology, such as solder reflow processes and other assembly processes.

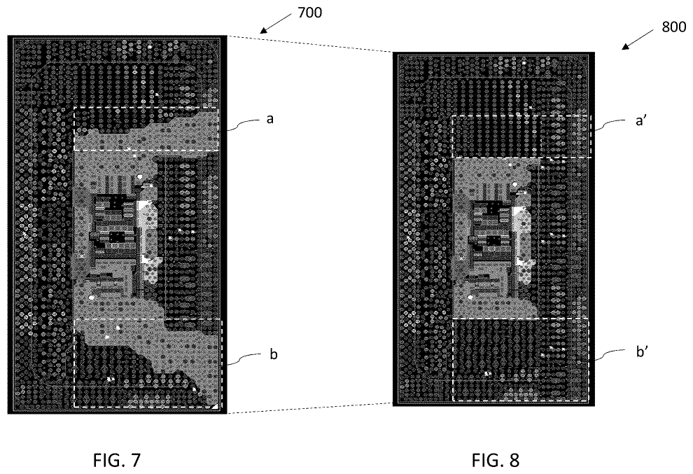

FIG. 7 shows a representative view of a ball grid array for a conventional semiconductor platform 700, which is provided for comparison with FIG. 8 that shows a representative view of a ball grid array for a present semiconductor platform 800 according to an aspect of the present disclosure. In FIG. 7, the regions a and b have a significant portion of the solder balls assigned for providing connections for power management. In FIG. 8, the regions a′ and b′ may have the solder balls being primarily assigned for providing input/output connections for signal management, which may result in a reduction in platform size, e.g., 10 percent, as well as a reduction in layer count. In an aspect, the ball grid array may have solder balls for power connections that are coupled to the interposer (not shown).

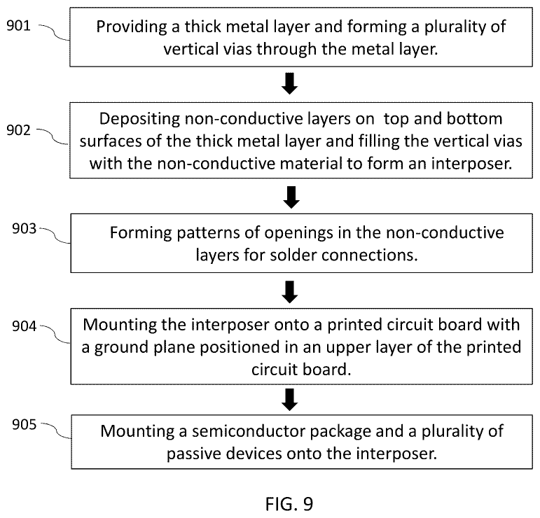

FIG. 9 shows a simplified flow diagram for an exemplary method according to an aspect of the present disclosure. In an aspect, the present method may be able to provide an interposer with a power corridor for semiconductor platforms.

The operation 901 may be directed to providing a thick metal layer or film and forming a plurality of vertical openings or vias through the metal layer.

The operation 902 may be directed to depositing non-conductive layers on the top and bottom surfaces of the thick metal layer and filling the vertical openings with the non-conductive material to form an interposer.

The operation 903 may be directed to forming patterns of openings in the non-conductive layers for solder connections.

The operation 904 may be directed to mounting the interposer onto a printed circuit board with a ground plane positioned in an upper layer of the printed circuit board.

The operation 905 may be directed to mounting a semiconductor package and a plurality of passive devices onto the interposer.

It will be understood that any property described herein for a specific semiconductor or system platform with an interposer having a power corridor may also hold for any semiconductor or system platform and interposer described herein. It will also be understood that any property described herein for a specific method may hold for any of the methods described herein. Furthermore, it will be understood that for any semiconductor or system platform with an interposer having a power corridor and the methods described herein, not necessarily all the components or operations described will be shown in the semiconductor platform, interposer, or method, but only some (not all) components or operations may be disclosed.

To more readily understand and put into practical effect the present semiconductor or system platform with an interposer having a power corridor, they will now be described by way of examples. For the sake of brevity, duplicate descriptions of features and properties may be omitted.

### Examples

Example 1 provides a semiconductor platform including a printed circuit board, an interposer coupled to the print circuit board, the interposer including a low-resistance conductive layer with a top surface and a bottom surface, the low-resistance conductive layer providing a power corridor for the semiconductor platform, a first non-conductive layer positioned on the top surface of the conductive layer and a second non-conductive layer positioned on the bottom surface of the conductive layer, and a plurality of vertical interconnects, for which the vertical interconnects provides electrical connections through the interposer, and a semiconductor package coupled to the interposer, for which the interposer provides the power corridor for the semiconductor package.
Example 2 may include the semiconductor platform of example 1 and/or any other example disclosed herein, further includes a voltage regulator or power management integrated circuit device coupled to the interposer, for which the interposer provides the power corridor for the voltage regulator or power management integrated circuit.
Example 3 may include the semiconductor platform of example 1 and/or any other example disclosed herein, further includes a first passive device coupled to the interposer, for which the interposer provides the power corridor for the first passive device.
Example 4 may include the semiconductor platform of example 3 and/or any other example disclosed herein, for which the first passive is an inductor.
Example 5 may include the semiconductor platform of example 1 and/or any other example disclosed herein, further includes a second passive device coupled to the interposer, for which the interposer provides the power corridor for the second passive device.
Example 6 may include the semiconductor platform of example 5 and/or any other example disclosed herein, for which the second passive device is an inductor, the inductor is attached to the printed circuit board, and for which the interposer further includes an opening for accommodating the inductor.
Example 7 may include the semiconductor platform of example 1 and/or any other example disclosed herein, for which the plurality of vertical interconnects includes a first vertical interconnect through the interposer coupling the semiconductor package to a ground plane positioned in an upper layer of the printed circuit board.
Example 8 may include the semiconductor platform of example 1 and/or any other example disclosed herein, for which the plurality of vertical interconnects includes a second vertical interconnect through the interposer coupling the semiconductor package to a signal line in the printed circuit board.
Example 9 may include the semiconductor platform of example 2 and/or any other example disclosed herein, for which the plurality of vertical interconnects includes a third vertical interconnect through the interposer coupling the voltage regulator or power management integrated circuit device to a ground plane positioned in an upper layer of the printed circuit board.
Example 10 may include the semiconductor platform of example 1 and/or any other example disclosed herein, further includes a ball grid array with a plurality of solder balls for power connections, for which the plurality of solder balls for power connections are coupled to the interposer.
Example 11 may include the semiconductor platform of example 1 and/or any other example disclosed herein, for which the low-resistance conductive layer has a thickness in the range of approximately 50 to 200 μm.
Example 12 provides a method that includes providing a low-resistance metal layer with a top surface and a bottom surface, the low-resistance metal layer providing a power corridor for the semiconductor platform, forming a plurality of vertical openings through the metal layer, forming a first non-conductive layer positioned on the top surface of the low-resistance metal layer and a second non-conductive layer positioned on the bottom surface of the low-resistance metal layer, filling the plurality of vertical openings to form non-conductive vertical separators for a plurality of vertical interconnects in the low-resistance metal layer, for which the first non-conductive layer, the low-resistance metal layer, the second non-conductive layer, and the plurality of vertical interconnects form an interposer with the power corridor, and forming a first pattern of openings for solder connections in the first non-conductive layer and a second pattern of openings for solder connections in the second non-conductive layer.
Example 13 may include the method of example 12 and/or any other example disclosed herein, further includes providing a device opening in the interposer by forming a space in the interposing and depositing a sacrificial material in the space and removing the sacrificial material to form the device opening.
Example 14 may include the method of example 12 and/or any other example disclosed herein, further includes positioning and coupling the interposer onto a printed circuit board with a ground plane positioned in an upper layer of the printed circuit board, and positioning and coupling a semiconductor package and a plurality of passive devices onto the interposer, for which the semiconductor package and one or more of the plurality of passive devices are coupled to the ground plane.
Example 15 provides an interposer including a low-resistance metal layer with a top surface and a bottom surface, the low-resistance metal providing a power corridor between a plurality of devices coupled to the top surface and a printed circuit board coupled to the bottom surface, a first non-conductive layer positioned on the top surface of the metal layer, for which the first non-conductive layer provides a first pattern of openings for solder connections, a second non-conductive layer positioned on the bottom surface of the metal layer, for which the second non-conductive layer provides a second pattern of openings for solder connections, and a plurality of vertical interconnects formed in the low-resistance metal layer separated by non-conductive vertical separators.
Example 16 may include the interposer example 15 and/or any other example disclosed herein, for which the plurality of vertical interconnects further includes ground vertical interconnects coupling a plurality of devices to a ground plane positioned in an upper layer of a printed circuit board, and signal vertical interconnects coupling the plurality of devices to input-output traces in the printed circuit board.
Example 17 may include the interposer example 15 and/or any other example disclosed herein, for which the interposer has one or more openings to accommodate tall devices coupled to a print circuit board.
Example 18 may include the interposer example 15 and/or any other example disclosed herein, for which the low-resistance metal layer is copper.
Example 19 may include the interposer example 15 and/or any other example disclosed herein, for which the low-resistance metal layer has a thickness in the range of approximately 50 to 200 μm.
Example 20 may include the interposer example 15 and/or any other example disclosed herein, for which the low-resistance metal layer has a thickness greater than 120 μm.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A semiconductor platform comprising:
a printed circuit board;
an interposer coupled to the print circuit board, the interposer comprising:
a low-resistance conductive layer with a top surface and a bottom surface, the low-resistance conductive layer providing a power corridor for the semiconductor platform;
a first non-conductive layer positioned on the top surface of the conductive layer and a second non-conductive layer positioned on the bottom surface of the conductive layer; and
a plurality of vertical interconnects, wherein the vertical interconnects provide electrical connections through the interposer; and
a semiconductor package coupled to the interposer, wherein the interposer provides the power corridor for the semiconductor package.

2. The semiconductor platform of claim 1, further comprises:
a voltage regulator or power management integrated circuit device coupled to the interposer, wherein the interposer provides the power corridor for the voltage regulator or power management integrated circuit.

3. The semiconductor platform of claim 1, further comprises:
a first passive device coupled to the interposer, wherein the interposer provides the power corridor for the first passive device.

4. The semiconductor platform of claim 3, wherein the first passive device is an inductor.

5. The semiconductor platform of claim 1, further comprises:
a second passive device coupled to the interposer, wherein the interposer provides the power corridor for the second passive device.

6. The semiconductor platform of claim 5, wherein the second passive device is an inductor, wherein the inductor is attached to the printed circuit board; and wherein the interposer further comprises an opening for accommodating the inductor.

7. The semiconductor platform of claim 1, wherein the plurality of vertical interconnects comprises a first vertical interconnect through the interposer coupling the semiconductor package to a ground plane positioned in an upper layer of the printed circuit board.

8. The semiconductor platform of claim 1, wherein the plurality of vertical interconnects comprises a second vertical interconnect through the interposer coupling the semiconductor package to a signal line in the printed circuit board.

9. The semiconductor platform of claim 2, wherein the plurality of vertical interconnects comprises a third vertical interconnect through the interposer coupling the voltage regulator or power management integrated circuit device to a ground plane positioned in an upper layer of the printed circuit board.

10. The semiconductor platform of claim 1, further comprises a ball grid array with a plurality of solder balls for power connections, wherein the plurality of solder balls for power connections are coupled to the interposer.

11. The semiconductor platform of claim 1, wherein the low-resistance conductive layer has a thickness in the range of approximately 50 to 200 μm.

12. A method comprising:
providing a low-resistance metal layer with a top surface and a bottom surface, the low-resistance metal layer providing a power corridor for the semiconductor platform;
forming a plurality of vertical openings through the metal layer;
forming a first non-conductive layer positioned on the top surface of the low-resistance metal layer and a second non-conductive layer positioned on the bottom surface of the low-resistance metal layer;
filling the plurality of vertical openings to form non-conductive vertical separators for a plurality of vertical interconnects in the low-resistance metal layer, wherein the first non-conductive layer, the low-resistance metal layer, the second non-conductive layer, and the plurality of vertical interconnects form an interposer with the power corridor; and
forming a first pattern of openings for solder connections in the first non-conductive layer and a second pattern of openings for solder connections in the second non-conductive layer.

13. The method of claim 12, further comprises providing a device opening in the interposer by forming a space in the interposing and depositing a sacrificial material in the space; and
removing the sacrificial material to form the device opening.

14. The method of claim 12, further comprises:
positioning and coupling the interposer onto a printed circuit board with a ground plane positioned in an upper layer of the printed circuit board; and
positioning and coupling a semiconductor package and a plurality of passive devices onto the interposer, wherein the semiconductor package and one or more of the plurality of passive devices are coupled to the ground plane.

15. An interposer comprising:
a low-resistance metal layer with a top surface and a bottom surface, the low-resistance metal layer providing a power corridor between a plurality of devices coupled to the top surface and a printed circuit board coupled to the bottom surface;
a first non-conductive layer positioned on the top surface of the metal layer, wherein the first non-conductive layer provides a first pattern of openings for solder connections;
a second non-conductive layer positioned on the bottom surface of the metal layer, wherein the second non-conductive layer provides a second pattern of openings for solder connections; and
a plurality of vertical interconnects formed in the low-resistance metal layer separated by non-conductive vertical separators.

16. The interposer of claim 15, wherein the plurality of vertical interconnects further comprises ground vertical interconnects coupling a plurality of devices to a ground plane positioned in an upper layer of a printed circuit board, and signal vertical interconnects coupling the plurality of devices to input-output traces in the printed circuit board.

17. The interposer of claim 15, wherein the interposer has one or more openings to accommodate tall devices coupled to a print circuit board.

18. The interposer of claim 15, wherein the low-resistance metal layer is copper.

19. The interposer of claim 15, wherein the low-resistance metal layer has a thickness in the range of approximately 50 to 200 μm.

20. The semiconductor platform of claim 15, wherein the low-resistance metal layer has a thickness greater than 120 μm.
